(19) United States
(12) Patent Application Publication
(10) Pub. No.: US 2026/0328850 A1
(43) Pub. Date: Oct. 22, 2026

(54) BATTERY-POWERED DEVICE

(71) Applicant: Nordic Semiconductor ASA, Trondheim (NO)

(72) Inventors: Audun KORNELIUSSEN, Trondheim (NO); Tharaka KAUSHALYA, Oulu (FI)

(73) Assignee: Nordic Semiconductor ASA, Trondheim (NO)

(21) Appl. No.: 19/103,505

(22) PCT Filed: Aug. 17, 2023
(86) PCT No.: PCT/EP2023/072682

§ 371 Date: Feb. 12, 2025

(30) Foreign Application Priority Data
Aug. 17, 2022 (GB) 2212015.8

(51) Int. Cl. G01R 31/3842; G01R 31/367; G01R 31/374; G01R 31/378

(52) U.S. Cl. CPC G01R 31/3842; G01R 31/367; G01R 31/374; G01R 31/378

(57) ABSTRACT

A battery-powered device is disclosed comprising a battery and a voltage sensor arranged to measure a terminal voltage of the battery. The battery-powered device is arranged to: a) determine a current flowing into or out of the battery, b) predict a terminal voltage of the battery using the current and an estimated state of charge of the battery, c) measure an actual terminal voltage of the battery using the voltage sensor, d) compare the predicted terminal voltage with the actual terminal voltage and e) update the estimated state of charge of the battery based on said comparison. The battery-powered device is arranged to repeat steps (a)-(e) at one or more subsequent times, said one or more subsequent times being determined based on an operating state of the battery-powered device.

### BACKGROUND OF THE INVENTION

The present invention relates to assessing a state of charge of a battery in a battery-powered device such as an Internet-of-Things (IoT) device.

Battery-powered devices are very common. It is useful to be able to assess the state of charge (SOC) of the battery in such devices, for instance to estimate how much longer the device can operate for before the energy stored in the battery is depleted. Having an accurate estimate of the battery SOC may be particularly useful for devices in remote and/or difficult-to-access locations (e.g. IoT sensors), because physical servicing to replace or recharge the battery can be planned in advance, before the battery is entirely depleted. This may improve reliability and cost efficiency. In some devices operational-level decisions are made based on an estimated SOC, so estimation errors can have large impacts on device operation.

The power demands of a battery-powered device may vary over time (e.g. as the device performs different functions and/or enters different modes of operation and/or operates in different ambient conditions). This can make it difficult to accurately assess the energy used by the device and the SOC of the battery at a given moment.

Existing techniques for assessing a battery SOC may not be suitable or sufficiently accurate for some applications and may use a relatively large amount of energy, which is undesirable for small capacity batteries such as those used in IoT devices.

An improved approach may be desired.

### SUMMARY OF THE INVENTION

According to a first aspect of the present invention there is provided a battery-powered device comprising:
a battery; and
a voltage sensor arranged to measure a terminal voltage of the battery; wherein the battery-powered device is arranged to:
   a) determine a current flowing into or out of the battery;
   b) predict a terminal voltage of the battery using the current and an estimated state of charge of the battery;
   c) measure an actual terminal voltage of the battery using the voltage sensor;
   d) compare the predicted terminal voltage with the actual terminal voltage;
   e) update the estimated state of charge of the battery based on said comparison; and
   repeat steps (a)-(e) at one or more subsequent times, said one or more subsequent times being determined based on an operating state of the battery-powered device.

According to a second aspect of the present invention there is provided a method for assessing a state of charge of a battery in a battery-powered device, the method comprising:
a) determining a current flowing into or out of the battery;
b) predicting a terminal voltage of the battery using the current and an estimated state of charge of the battery;
c) measuring an actual terminal voltage of the battery;
d) comparing the predicted terminal voltage with the actual terminal voltage;
e) updating the estimated state of charge of the battery based on said comparison; and
repeating steps (a)-(e) at one or more subsequent times, said one or more subsequent times being determined based on an operating state of the battery-powered device.

According to a third aspect of the present invention there is provided computer software comprising instructions that, when executed by a processor of a battery-powered device, cause the processor to:
a) determine a current flowing into or out of a battery of the battery-powered device;
b) predict a terminal voltage of the battery using the current and an estimated state of charge of the battery;
c) receive data indicating an actual terminal voltage of the battery;
d) compare the predicted terminal voltage with the actual terminal voltage; e) update the estimated state of charge of the battery based on said comparison; and
repeat steps (a)-(e) at one or more subsequent times, said one or more subsequent times being determined based on an operating state of the battery-powered device.

Thus, it will be appreciated by those skilled in the art that the state of charge of the battery may be estimated accurately throughout device operation without using excessive power because the steps (a)-(e) are repeated dynamically based on an operating state of the device. In some embodiments, steps (a)-(e) are repeated at times corresponding to a fixed repetition interval, with the repetition interval depending on the operating state of the battery powered device. For example, the device may repeat steps (a)-(e) to update its estimate of the state of charge more frequently when the device is operating in a state with a high and/or varied current flow (e.g. drawing a high discharge current when actively performing radio communication) and less frequently when the device is operating in a state with a lower and/or more stable current flow (e.g. drawing a low discharge current during a lower power sleep mode).

In a set of embodiments, the battery-powered device is arranged to operate in a first operating state and a second operating state. The first operating state may correspond to an awake mode (e.g. in which the device executes one or more primary functions such as data logging, data processing or RF communication). The second operating state may correspond to a sleep mode (e.g. in which main functions of the battery-powered device are not performed).

In a set of embodiments, steps (a)-(e) are repeated at a first rate when the battery-powered device is in the first operating state. The device may draw a high and/or less predictable current when in the first operating state, meaning that it may be desirable to regularly update the estimated state of charge.

In a set of embodiments, steps (a)-(e) are repeated at a second, lower rate when the battery-powered device is in the second operating state. For instance, in a sleep mode the device may be expected to draw very little current from the battery. It may be acceptable to update the estimated state of charge of the battery less frequently when the device is in a sleep mode because the absolute change in battery SOC may be expected to be lower and/or more predictable.

In some embodiments, the device is arranged to operate in one or more operating states in which steps (a)-(e) are not performed. For instance, the battery-powered device may be arranged to not repeat steps (a)-(e) when in a second operating state such as a sleep mode.

In some embodiments, steps (a)-(e) are repeated at a time corresponding to a transition between said first and second operating states. For instance, the battery-powered device may perform steps (a)-(e) when (or soon before or soon after) transitioning to a first operating state after a period of operating in the second operating state (e.g. when waking from a period of sleep). In embodiments where steps (a)-(e) are repeated when moving to a first state after a period of second state operation, the determined current may comprise a current flowing into or out of the device during the period of second state operation (e.g. a current drawn from the battery during the sleep mode preceding the present awake mode).

The one or more times at which steps (a)-(e) are repeated may also be based on other considerations. For instance, the performance of many batteries can vary at different levels of state of charge. For instance, when the state of charge of a battery is low (e.g. less than 10% of a theoretical fully-charged state), it may exhibit substantially different internal resistances to the fully-charged battery. This may lead to an increased uncertainty in the estimated state of charge. Therefore, in a set of embodiments, the one or more times at which steps (a)-(e) are repeated are determined based on the estimated state of charge of the battery. An interval between repetitions may decrease monotonically with the estimated state of charge (i.e. if all other parameters were to be held constant). In other words, steps (a)-(e) may be repeated more regularly when the battery is estimated to have a lower state of charge.

Battery performance can also be affected by temperature. In a set of embodiments, additionally or alternatively, the one or more times at which steps (a)-(e) are repeated may be determined based on a temperature of the battery-powered device (e.g. a temperature of the battery). An interval between repetitions may decrease monotonically with the temperature (i.e. if all other parameters were to be held constant). In other words, steps (a)-(e) may be repeated more regularly when the temperature is lower. The battery-powered device may comprise a temperature sensor arranged to measure a temperature of the battery-powered device (e.g. a temperature of the battery).

The current may comprise a current flowing into the battery (a charging current) or a current flowing out of the battery (a discharging current). The current may comprise an average current flowing into or out of the battery since a state of charge of the battery was previously estimated (e.g. since steps (a)-(e) were last performed). The current may comprise an instantaneous current flowing into or out of the battery (e.g. when the state of charge was estimated recently).

An initial estimate of state of charge of the battery (i.e. the first time steps (a)-(e) are performed) may comprise a predetermined state of charge (e.g. retrieved in a memory) or a state of charge calculated from a set of initial battery parameters (e.g. calculated from initial sensor measurements and/or assumptions).

In a set of embodiments, determining the current flowing into or out of the battery comprises measuring the current. Accordingly, the battery-powered device may be arranged to determine the current flowing into or out of the battery by measuring the current flowing into or out of the battery. The battery-powered device may comprise a current sensor arranged to measure current flowing into or out of the battery. The current sensor may be arranged to measure charging currents and discharging currents.

However, it may in some situations be difficult to measure accurately the battery current. For instance, when the device uses very small amounts of current (e.g. in a sleep mode) the current may be near to the noise floor of a current sensor dimensioned to also measure much larger operational currents. Using a current sensor with a large dynamic range may be expensive. In a set of embodiments, the current flowing into or out of the battery is determined based on an operating state of the battery-powered device. The inventors have recognised that in some operating states the device may experience reasonably predictable current flows, which can be used to determine an estimate of the current without necessarily needing to perform direct measurements.

In some embodiments, determining the current comprises retrieving a stored current corresponding to the operating state of the battery-powered device. Accordingly, the battery-powered device may be arranged to determine the current flowing into or out of the battery by retrieving a stored current corresponding to the operating state of the battery-powered device from a memory (e.g. from an internal or external memory). The stored current may be an expected charging or discharging current for that operating state (e.g. based on design specifications and/or a previously measured current). In a set of embodiments, the current of the battery is estimated to be equal to an expected current for the operating state of the battery-powered device. The current may be determined using a combination (e.g. a weighted sum) of measured and stored currents.

Different methods of determining the current may be used at different times, e.g. based on the operating state of the battery-powered device. For instance, the battery-powered device may be arranged to determine the current based solely or in part on a measured current during or following a period of operation in a first operating state (e.g. a higher current mode such as an active mode). The battery-powered device may be arranged to determine the current based solely or in part on the operating state of the battery-powered device during or following a period of operation in a second operating state (e.g. a low current mode such as a sleep mode).

In a set of embodiments, predicting the terminal voltage comprises using a temperature of the battery-powered device (i.e. in addition to the current and the estimated state of charge of the battery), e.g. a temperature measured by a temperature sensor. As mentioned above, battery performance can also be affected by temperature, so it may be advantageous to take the temperature into account when predicting battery behaviour.

Predicting the terminal voltage of the battery may comprise using a model of the battery. The model may comprise an equivalent circuit model (ECM). In some embodiments, the battery is modelled as an open circuit voltage connected in series with an internal resistance and at least one RC network. The model may comprise one or more parameters. The parameters may correspond to one or more physical properties of the battery (e.g. the sizes of the internal resistance and/or components in the RC network) and/or one or more operating conditions (e.g. temperature). One or more parameters may be estimates of physical properties of the battery. The battery-powered device may be arranged to retrieve one or more parameters of a battery model from a memory, e.g. from an internal or external memory. For instance, one or more parameters may be retrieved by looking up one or more parameters corresponding to a present operating condition and/or a physical property of the battery.

The battery-powered device may be arranged to determine one or more parameters of said model. The battery-powered device may be arranged to determine one or more parameters of said model by simply retrieving one or more stored parameters and/or by modifying one or more stored parameters (e.g. by interpolating between and/or extrapolating from stored parameters).

One or more parameters of said model may be determined based on battery characterisation information (e.g. determined from characterisation tests carried out for a variety of battery chemistries and at a variety of battery temperatures). For instance, one or more parameters of said model may be determined based on a chemistry of the battery. One or more parameters of said model may be determined based on a temperature of the battery. One or more parameters of said model may be determined based on the estimated state of charge of the battery. In some embodiments, one or more parameters of said model may be determined by interpolating stored parameters (e.g. if a present battery temperature falls between two temperatures tested in a characterisation test).

In a set of embodiments, one or more parameters of the model (e.g. an internal resistance) may be determined using one or more values of the actual terminal voltage of the battery and/or the current flowing into or out of the battery. For instance, the device may be arranged to determine one or more parameters of the model using an instantaneous determined value of the current flowing into or out of the battery and/or an instantaneous measured value of the actual terminal voltage.

However, using single instantaneous values of voltage and/or current to determine one or more parameters may not be sufficiently accurate or reliable. Therefore, in a set of embodiments the device is arranged to determine one or more parameters of the model using a plurality of values of the current flowing into or out of the battery and/or the actual terminal voltage. For instance, the device may be arranged to determine (or estimate) a change in terminal voltage and/or current over time (e.g. a voltage and/or current time gradient), and use the determined change(s) to determine one or more parameters of the model.

The device may be arranged to determine a change between the determined current and/or the measured terminal voltage at the present iteration of steps (a)-(e) and a previous time (e.g. a previous iteration of steps (a)-(e)).

In a set of embodiments, the model includes an internal resistance parameter (e.g. an estimate of an internal resistance of the battery). In such embodiments, the device may be arranged to determine the internal resistance parameter by dividing a terminal voltage value (e.g. an instantaneous terminal voltage measurement or a change in terminal voltage) by a current value (e.g. an instantaneous current or a change in current). In other words, the device may be arranged to determine the internal resistance using voltage and current values according to Ohm's law.

Using values of the actual terminal voltage and/or battery current to determine one or more parameters of the model may be useful in situations where other approaches for determining parameters of the model are unavailable or unreliable. For instance, battery characterisation information may not be available or reliable for all conditions in which the battery-powered device is operated. For example, at low temperatures (e.g. near or below 0° C.), the internal resistance of many batteries may become very non-linear, reducing the usefulness of previously-stored characterisation test results.

Instantaneous measurements of the voltage and/or current may have large uncertainties, which can lead to noise in the determined parameter(s). Thus, in some embodiments, the device is arranged to condition values of the voltage and/or current before using them to determine one or more parameter(s). For instance, the device may be arranged to filter out one or more values of voltage and/or current, i.e. to determine the one or more parameters using only values of the voltage and/or current that satisfy one or more filter criteria. For instance, the device may be arranged to use only current and/or voltage values that are within an expected (e.g. practically feasible) range (e.g. within an expected distance of a previous current and/or voltage value).

One or more parameters of said model may be changed between repetitions of steps (a)-(e), e.g. as the temperature and/or estimated state of charge changes. In other words, predicting the terminal voltage of the battery may be done in different ways at different times. The battery powered device may be arranged to update one or more parameters of said model based on the comparison between the predicted terminal voltage and the actual terminal voltage. For instance, the model may be updated if a difference between the predicted terminal voltage and an actual terminal voltage is greater than a threshold (e.g. >100 mV). One or more parameters of said model may be updated based the estimated state of charge. For instance, the model may be updated if the estimated state of charge drops below a threshold (e.g. 20%). This threshold may correspond to a state of charge where battery nonlinearities dominate.

In some embodiments, one or more parameters of the model (e.g. an internal resistance) is updated by using updated values for the terminal voltage of the battery and/or the current flowing into or out of the battery. In other words, the device may be arranged to repeatedly determine one or more parameters using one or more values of the actual terminal voltage of the battery and/or the current flowing into or out of the battery, i.e. to update the determined parameter as the voltage and current values change.

In some embodiments, the device is arranged to condition the parameter(s) determined using values of the actual terminal voltage of the battery and/or the current flowing into or out of the battery before using them in the model. For instance, the device may be arranged to filter out one or more of the determined parameters. For instance, the device may be arranged to use in the model only those parameter values that are within an expected (e.g. practically feasible) range of a previous value of that parameter.

Additionally or alternatively, the device may be arranged to use a moving average of the one or more determined parameters in the model. The moving average may comprise a simple moving average (i.e. an unweighted mean over a fixed number of most-recent parameter values). Alternatively, the moving average comprises a weighted moving average, with different weights applied to the results of different determinations of the parameter. For instance, more recent values for the parameter may be weighted higher than older values. In a set of embodiments, the device is arranged to use an exponential moving average of a parameter in the equivalent circuit battery model (i.e. in which the weight applied to a parameter value decreases exponentially as it ages). In a set of embodiments, the device is arranged to use a double exponential moving average (DEMA) of a parameter in the equivalent circuit battery model.

In a set of embodiments, the device is arranged to set parameters of the model in different ways at different times. For instance, in a first set of operating conditions (e.g. when the temperature is in a first temperature range and/or the state of charge is in a first state of charge range), the device may be arranged to retrieve one or more parameters of a battery model from a memory. In a second set of operating conditions (e.g. when the temperature is in a second temperature range and/or the state of charge is in a second state of charge range), the device may be arranged to determine one or more parameters of the model using one or more values of the actual terminal voltage of the battery and/or the current flowing into or out of the battery.

For example, the inventors have recognised that at low temperatures, previously-stored characterisation information for the internal resistance of the battery may be unavailable, unreliable or inaccurate. Thus, in a set of embodiments, the device is arranged, when the temperature is above a temperature threshold, to retrieve an internal resistance parameter of the model from a memory. Conversely, the device may be arranged, when the temperature is below the temperature threshold, to determine the internal resistance parameter of the model using one or more values of the actual terminal voltage of the battery and/or the current flowing into or out of the battery (e.g. using Ohm's law). The temperature threshold may be at or near 0° C. (e.g. between −15° C. and +15° C., between −10° C. and +10° C., between −5° C. and +5° C. or between −2° C. and +2° C.).

The device may comprise one or more sensors (e.g. a temperature sensor) arranged to detect whether the device is in the first set of operating conditions or the second set of operating conditions (e.g. whether the temperature is below or above a threshold). The sensor(s) may control the way in which the one or more parameters are set by the device according to said detection.

The model may have an associated modelling uncertainty (i.e. modelling noise). This may reflect the quality of the model. The battery-powered device may be arranged to estimate a modelling noise. The battery-powered device may be arranged to update an estimate of modelling noise (e.g. if the predicted terminal voltage differs significantly to the actual terminal voltage and/or if the estimated state of charge drops below a threshold). An estimate of modelling noise may be used when predicting the terminal voltage of the battery and/or when updating the estimated state of charge of the battery.

Sensor measurements used in some embodiments (e.g. the terminal voltage, the current and/or a temperature) may have an associated measurement uncertainty (i.e. measurement noise). The battery-powered device may be arranged to estimate a measurement noise associated with one or more sensor measurements. The battery-powered device may be arranged to update an estimate of measurement noise (e.g. if the predicted terminal voltage differs significantly to the actual terminal voltage and/or if the estimated state of charge drops below a threshold). An estimate of measurement noise may be used when predicting the terminal voltage of the battery and/or when updating the estimated state of charge of the battery.

In some embodiments, steps (a)-(e) comprise a Kalman filter algorithm. Some embodiments may utilise an extended Kalman filter algorithm (i.e. a nonlinear Kalman filter) to estimate the state of charge of the battery. The state of charge of the battery may comprise a state variable in said Kalman filter algorithm.

In some embodiments the battery is a rechargeable battery such as a Nickel-Cadmium, Nickel-Metal Hydride or Lithium Ion battery. It has been recognised that the present invention may be particularly suitable for batteries with a relatively small capacity. The battery may comprise a nominal capacity of 10 Wh or less, e.g. 5 Wh or less, 1 Wh or less, 0.5 Wh or less or even 0.1 Wh or less. The battery may have a nominal unloaded terminal voltage of less than 20 V, less than 10 V or less than 5 V (e.g. 3.7 V or 3.8 V).

The battery-powered device may comprise a processor. The battery-powered device may comprise a memory storing software instructions that, when executed by the processor, cause the processor to execute one or more of steps (a)-(e). The processor may also be arranged to execute one or more other functions of the battery-powered device (e.g. application functions such as RF communications).

One or more sensors of the battery-powered device (e.g. the voltage sensor, a current sensor and/or temperature sensor) may be analogue sensors, i.e. arranged to produce analogue signals indicative of the sensed quantity (e.g. voltage, current or temperature). Additionally or alternatively, one or more sensors of the battery-powered device may be digital sensor arranged to produce digital signals indicative of the sensed quantity.

The processor may be arranged to receive signals directly from one or more sensors (e.g. from the voltage sensor, a current sensor and/or a temperature sensor). In some embodiments, additionally or alternatively, the battery-powered device comprises a power management integrated circuit (PMIC) arranged to receive signals from one or more sensors and to send said signals or information derived from said signals to the processor. In a set of embodiments the PMIC is be arranged to receive signals from the voltage sensor and to send said signals or terminal voltage information derived from said signals to the processor. For instance, the PMIC may comprise one or more analogue-to-digital converters arranged to convert analogue signals produced by the one or more sensors into digital signals that can be processed by the processor. In other words, the PMIC may act as a sensor interface.

Features of any aspect or embodiment described herein may, wherever appropriate, be applied to any other aspect or embodiment described herein. Where reference is made to different embodiments, it should be understood that these are not necessarily distinct but may overlap.

### BRIEF DESCRIPTION OF THE DRAWINGS

One or more non-limiting examples will now be described, by way of example only, and with reference to the accompanying figures in which:

FIG. 1 shows a battery-powered device according to an embodiment of the present invention;

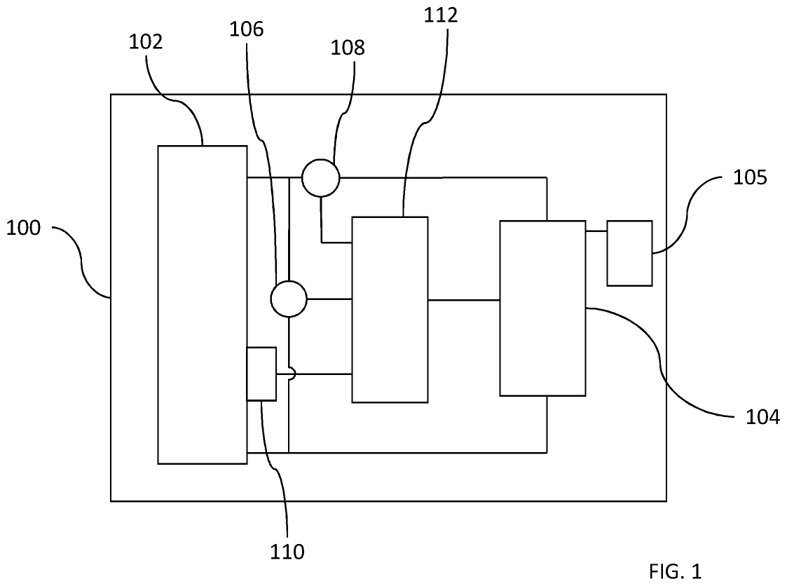

FIG. 2 is a block diagram of an equivalent circuit model for use in embodiments of the present invention; and

FIG. 3 is a flow diagram illustrating a method of assessing the state of charge of a battery in the battery-powered device of FIG. 1.

### DETAILED DESCRIPTION

A battery-powered device 100 comprises a battery 102, a microprocessor 104, a memory 105, a voltage sensor 106, a current sensor 108, a temperature sensor 110 and a power management integrated circuit (PMIC) 112. The battery 102 powers the battery-powered device 100.

The voltage sensor 106 senses the terminal voltage V of the battery 102. The current sensor 108 senses the instantaneous current I flowing into or out of the battery 102. The temperature sensor 110 senses the temperature T of the battery 102. The voltage sensor 10, current sensor 108 and temperature sensor 110 are connected to the PMIC 112, which converts the sensing information into digital measurement data (e.g. using one or more analogue-to-digital converters (ADCs)). The PMIC 112 sends the measurement data to the microprocessor 104.

The battery-powered device 100 is operable in an awake mode, in which the microprocessor 104 controls various normal device functions such as data collection or RF communications. The device 100 is also operable in a sleep mode in which many of the normal device functions are paused to conserve power.

One of the functions performed by the microprocessor 104 is to estimate the state of charge (SOC) of the battery 102, using measurements from the sensors 106, 108, 110 and a model of the battery 102.

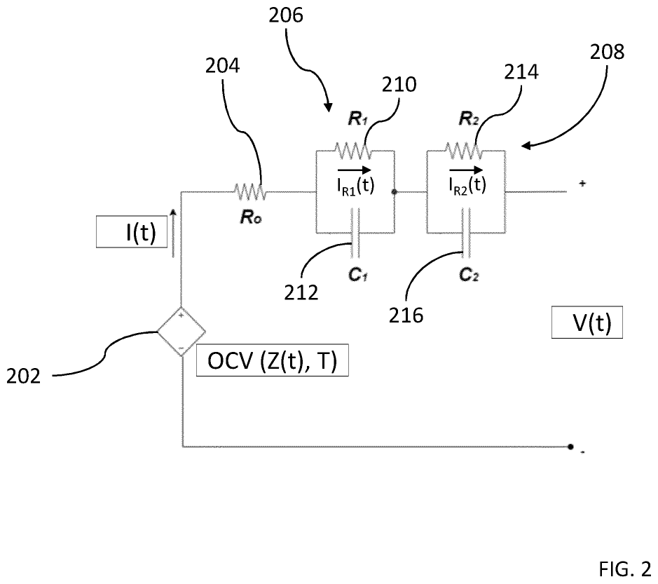

The model of the battery 102 used by the microprocessor 104 is shown in FIG. 2. In this model, the battery 102 comprises a voltage source 202 having an open circuit voltage OCV. The OCV is a function of the state of charge Z of the battery 102, which changes over time, and the current temperature, T. The model of the battery 102 also comprises an internal series resistor 204 with resistance R₀, a first RC element 206 and a second RC element 208. The internal series resistor 204 models the instantaneous polarization of the battery voltage and the first and second RC elements 206, 208 model diffusion voltage characteristics of the battery 102. The first RC element 206 comprises a first resistor 210 having resistance R₁ in parallel with a first capacitor 212 having capacitance C₁. Similarly, the second RC element 208 comprises a second resistor 214 having resistance R₂ in parallel with a second capacitor 216 having capacitance C₂. The resistances and capacitances of the RC elements 206, 208, and the OCV function are chosen based on characterisation tests carried out at different temperatures.

The battery current flowing through the internal series resistor 204 is I(t) (this can be positive or negative depending on whether it is a discharging or charging current). The currents flowing through the first and second resistors 210, 214 are I_{R1}(t) and I_{R2}(t), respectively. The terminal voltage of the battery 102 is V(t).

The microprocessor 104 uses an extended Kalman filter technique to estimate the state of charge of the battery 102. In the equations below, Z[N] is the state of charge of the battery in time step N, Δt is the length of each time step, Q(T) is the total battery capacity at temperature T, β is the Faradic efficiency and I[N] is the current flowing into or out of the battery in time step N.

The state of charge at a time step N+1 is given as:

$$Z [ N + 1 ] = Z [ N ] - \frac{Δ t}{Q} \times β \times I [ N ] . \qquad ( 1 )$$

The currents flowing through the first and second resistors 210, 214 at a time step N+1 are:

$${I [ N + 1 ]}_{{R}_{1}} = {e}^{( - \frac{Δ t}{{C}_{1} {R}_{1}} )} {I [ N ]}_{{R}_{1}} - ( 1 - {e}^{( - \frac{Δ t}{{C}_{1} {R}_{1}} )} ) I [ N ] \qquad ( 2 )$$

$${I [ N + 1 ]}_{{R}_{2}} = {e}^{( - \frac{Δ t}{{C}_{2} {R}_{2}} )} {I [ N ]}_{{R}_{2}} - ( 1 - {e}^{( - \frac{Δ t}{{C}_{2} {R}_{2}} )} ) I [ N ] \qquad ( 3 )$$

The modelled terminal voltage at a time step N depends on the values of the state vector equations:

Vₑₛₜ[N]=OCV(Z[N],T)−R₁I[N]R₁−R₂I[N]R₂−R₀I[N] (4)

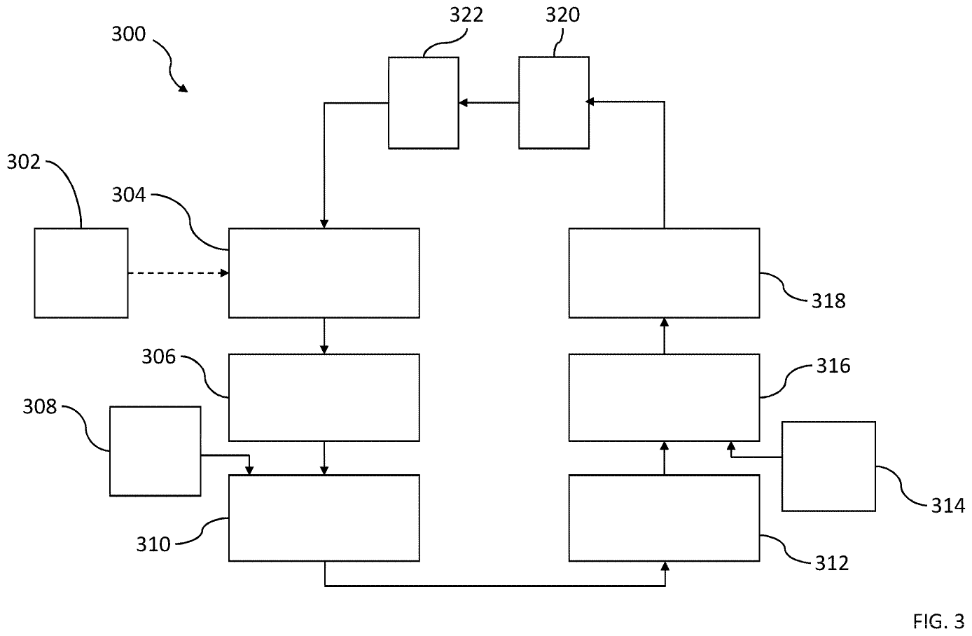

The operation of the battery-powered device 100 to estimate the state of charge of the battery 102 will now be explained with reference to the flow diagram 300 in FIG. 3. The battery-powered device 100 uses an extended Kalman filter method to estimate the state of charge of the battery 102.

On the first iteration of the method 300, in an initial step 302, an initial terminal voltage V₀ is measured with the voltage sensor 106, an initial current I₀ is measured with the current sensor 108 and a battery temperature T is measured with the temperature sensor 110. The microprocessor 104 retrieves from the memory 105 battery parameter values (e.g. resistance and capacitance values of the RC elements 206, 208) associated with the battery temperature T.

An initial estimate for the open circuit voltage OCV₀ of the battery 102 is calculated according to OCV₀=V₀+R₀(T)I₀. Using a look-up table stored in the memory 105, the microprocessor 104 identifies an initial estimate for the battery SOC Z₀ based on OCV₀ and T. The microprocessor 104 also retrieves expected measurement and modelling noise values (i.e. uncertainties) from the memory 105. The microprocessor 104 may interpolate between stored data if battery parameters and/or an initial state of charge is not available for the precise values of OCV₀ and T.

In step 304, at a time step N, a prediction of the state of charge of the battery 102 is calculated. In the first iteration, the predicted SOC Z[N] is calculated using the initial estimate for the battery SOC Z₀ determined in step 302. In later iterations, step 304 may involve updating model parameters and then calculating a prediction for Z[N] based on a previous state estimate and the updated model (explained further below in more detail).

In step 306, a state covariance of the predicted SOC Z[N] is calculated based on Z[N] and the measurement and modelling uncertainties.

In step 308, the device determines the current I flowing into or out of the battery 102 (i.e. a charging or discharging current). When the device 100 is operating in the awake mode (and is not being charged), it determines the current by using the current sensor 108 to measure the current I flowing out of the battery 102. When the device 100 has just transitioned into the awake mode from the sleep mode, a predetermined sleep current is used as the current I. This may be more accurate than actively measuring the low current used during sleep.

In step 310, the microprocessor 104 uses the current I and Z[N] in equations (2)-(4) to predict a terminal voltage Vₑₛₜ[N].

In step 312, a Kalman gain is calculated from the measurement and modelling uncertainties and the state covariance.

In step 314, the voltage sensor 106 is used to measure the actual terminal voltage V_{actual}[N] of the battery 102.

In step 316, the actual terminal voltage V_{actual}[N] is compared with the predicted terminal voltage voltage Vₑₛₜ[N]. This is used with the Kalman gain to generate an updated state estimate for the SOC Z[N]. In step 318, the device calculates an updated estimate of the state covariance.

In step 320, the device waits until the next iteration of the method starts. The next iteration of the method starts at a time that depends on the operating state of the device 100.

In the awake mode, the SOC estimation method 300 repeats at a fixed rate, e.g. once per second. The SOC estimation process 300 is not performed when the device 100 is in the sleep mode, but is carried out when the device 100 next transitions from the sleep mode into the awake mode.

In step 322, the next iteration of the method begins, at time step N+1 (e.g. because a fixed interval has elapsed in the awake mode, or because the device has just transitioned from the sleep mode into the awake mode). The device takes a new temperature measurement T using the temperature sensor 110 and retrieves from the memory 105 battery parameter values associated with the battery temperature T.

The device may also update aspects of the filter in step 322. For instance, the device 100 may update modelling and measurement uncertainties when the previous estimated state of charge Z[N] is below a particular threshold (e.g. 25%), or when the measured terminal voltage V_{actual}[N] was significantly different to the predicted terminal voltage Vₑₛₜ[N] in the previous iteration.

In step 304, the device 100 calculates an updated prediction of the SOC Z[N+1] using the updated model parameters. The rest of the process then repeats as explained above.

Thus, the device 100 maintains an accurate estimate of the state of charge of the battery 102 throughout operation whilst still conserving energy in the sleep mode.

In the example described above, the parameter values used in the model of the battery 102 are determined from the results of characterisation tests that are determined and stored to the memory 105 in advance. However, in some examples the device 100 is operated in temperature ranges for which suitable characterisation test information is either unavailable or unreliable. For instance, at low or negative temperatures (i.e. temperatures below 0° C.), the internal resistance of many batteries may become very non-linear, reducing the usefulness of previously-stored characterisation test results.

Therefore, in another example the microprocessor 104 is arranged to set some parameter values of the model in different ways at different temperatures.

When the temperature is above a threshold (e.g. of 0° C.), the microprocessor 104 retrieves parameter values (including the internal resistance R₀) from the memory 105 corresponding to appropriate characterisation test results for the current temperature T (i.e. the approach described above).

However, when the temperature is below the threshold, the temperature sensor 110 triggers the microprocessor 104 to set the internal resistance R₀ of the model in a different way. When the temperature is below the threshold, at time t, the microprocessor 104 calculates an internal resistance R₀(t) of the battery 102 using measurements of the battery terminal voltage V measured with the voltage sensor 106 and current I measured with the current sensor 108 (i.e. determining R₀ on-the-fly). The internal resistance R₀(t) at time t is calculated from a change in the measured voltage and current over a short time window between a prior time t−1 and the current time t:

$${R}_{0} ( t ) = \frac{V ( t ) - V ( t - 1 )}{I ( t ) - I ( t - 1 )} \qquad ( 5 )$$

This estimate of internal resistance R₀ may not be as accurate as those determined from characterisation tests for higher temperatures, but this approach allows the battery model and the rest of the method to still be used in situations where pre-determined characterisation tests are unavailable or unreliable. The rest of the operation of the battery-powered device 100 to estimate the state of charge of the battery 102 continues as described above, with the internal resistance R₀ used in the model updated as appropriate based on the temperature and the measured current and voltage. In some example, a moving average (e.g. a double exponential moving average or DEMA) of the internal resistance R₀ is used in the model.

While the invention has been described in detail in connection with only a limited number of embodiments, it should be readily understood that the invention is not limited to such disclosed embodiments. Rather, the invention can be modified to incorporate any number of variations, alterations, substitutions or equivalent arrangements not heretofore described, but which are commensurate with the scope of the invention. Additionally, while various embodiments of the invention have been described, it is to be understood that aspects of the invention may include only some of the described embodiments. Accordingly, the invention is not to be seen as limited by the foregoing description, but is only limited by the scope of the appended claims.

1. A battery-powered device comprising:
a battery; and
a voltage sensor arranged to measure a terminal voltage of the battery;
wherein the battery-powered device is arranged to:
a) determine a current flowing into or out of the battery;
b) predict a terminal voltage of the battery using the current and an estimated state of charge of the battery;
c) measure an actual terminal voltage of the battery using the voltage sensor;
d) compare the predicted terminal voltage with the actual terminal voltage;
e) update the estimated state of charge of the battery based on said comparison; and
repeat steps (a)-(e) at one or more subsequent times, said one or more subsequent times being determined based on an operating state of the battery-powered device.

2. The battery-powered device as claimed in claim 1, arranged to operate in a first operating state corresponding to an awake mode and in a second operating state corresponding to a sleep mode.

3. The battery-powered device as claimed in claim 2, arranged to repeat steps (a)-(e) at a first rate when the battery-powered device is in the first operating state and to repeat steps (a)-(e) at a second, lower rate when the battery-powered device is in the second operating state.

4. The battery-powered device as claimed in claim 2, arranged to repeat steps (a)-(e) at a time corresponding to a transition between said first and second operating states.

5. (canceled)

6. The battery-powered device as claimed in claim 1, wherein the one or more times at which steps (a)-(e) are repeated are determined based on the estimated state of charge of the battery.

7. (canceled)

8. The battery-powered device as claimed in claim 1, wherein the one or more times at which steps (a)-(e) are repeated are determined based on a temperature of the battery-powered device.

9. (canceled)

10. (canceled)

11. The battery-powered device as claimed in claim 1, arranged to determine the current flowing into or out of the battery by retrieving a stored current corresponding to the operating state of the battery-powered device.

12. The battery-powered device as claimed in claim 1, arranged to predict the terminal voltage of the battery using a temperature of the battery-powered device.

13. The battery-powered device as claimed in claim 1, arranged to predict the terminal voltage of the battery using an equivalent circuit model of the battery.

14. (canceled)

15. The battery-powered device as claimed in claim 13, arranged to determine one or more parameters of the model using one or more values of the actual terminal voltage of the battery and/or the current flowing into or out of the battery.

16. The battery-powered device as claimed in claim 15, arranged to determine a change in terminal voltage and/or current over time, and use the determined change(s) to determine one or more parameters of the model.

17. The battery-powered device as claimed in claim 15, arranged to repeatedly determine one or more parameters using one or more values of the terminal voltage of the battery and/or the current flowing into or out of the battery, and to use a moving average of the one or more determined parameters in the model.

18. The battery-powered device as claimed in claim 13, wherein:
in a first set of operating conditions, the device is arranged to retrieve one or more parameters of the model from a memory; and
in a second set of operating conditions, the device is arranged to determine one or more parameters of the model using one or more values of the terminal voltage of the battery and/or the current flowing into or out of the battery.

19. The battery-powered device of claim 18, wherein:
the model includes an internal resistance parameter; and
the device is arranged:
when the temperature is above a temperature threshold, to retrieve an internal resistance parameter of the model from a memory; and
when the temperature is below the temperature, to determine the internal resistance parameter of the model using one or more values of the actual terminal voltage of the battery and/or the current flowing into or out of the battery.

20. The battery-powered device of claim 19, wherein the temperature threshold is between −5° C. and +5° C.

21. (canceled)

22. (canceled)

23. (canceled)

24. (canceled)

25. (canceled)

26. The battery-powered device as claimed in claim 1, wherein the battery is a rechargeable battery.

27. A method for assessing a state of charge of a battery in a battery-powered device, the method comprising:
a) determining a current flowing into or out of the battery;
b) predicting a terminal voltage of the battery using the current and an estimated state of charge of the battery;
c) measuring an actual terminal voltage of the battery;
d) comparing the predicted terminal voltage with the actual terminal voltage;
e) updating the estimated state of charge of the battery based on said comparison; and
repeating steps (a)-(e) at one or more subsequent times, said one or more subsequent times being determined based on an operating state of the battery-powered device.

28. A non-transitory computer readable medium comprising instructions that, when executed by a processor of a battery-powered device, cause the processor to:
a) determine a current flowing into or out of a battery of the battery-powered device;
b) predict a terminal voltage of the battery using the current and an estimated state of charge of the battery;
c) receive data indicating an actual terminal voltage of the battery;
d) compare the predicted terminal voltage with the actual terminal voltage;
e) update the estimated state of charge of the battery based on said comparison; and
repeat steps (a)-(e) at one or more subsequent times, said one or more subsequent times being determined based on an operating state of the battery-powered device.

29. The method of claim 27, wherein the battery-powered device is arranged to operate in a first operating state corresponding to an awake mode and in a second operating state corresponding to a sleep mode, and the method comprises repeating steps (a)-(e) at a first rate when the battery-powered device is in the first operating state and repeating steps (a)-(e) at a second, lower rate when the battery-powered device is in the second operating state.

30. The non-transitory computer readable medium of claim 28, wherein the instructions cause the processor to operate the battery-powered device in a first operating state corresponding to an awake mode and in a second operating state corresponding to a sleep mode, and to repeat steps (a)-(e) at a first rate when the battery-powered device is in the first operating state and repeating steps (a)-(e) at a second, lower rate when the battery-powered device is in the second operating state.
